(19) United States
(12) Patent Application Publication
(10) Pub. No.: US 2004/0019710 A1
(43) Pub. Date: Jan. 29, 2004

(54) Hard drive hot insertion and removal notifications

(76) Inventors: Neela Syam Kolli, Norcross, GA (US); Peter B. Jarrett, Lilburn, GA (US)

Correspondence Address: LSI LOGIC CORPORATION, 1621 BARBER LANE, MS: D-106 LEGAL, MILPITAS, CA, 95035, US

(21) Appl. No.: 10/206,604

(22) Filed: Jul. 26, 2002

(51) Int. Cl. G06F 13/00; H05K 7/10; G06F 3/00

(52) U.S. Cl. 710/19; 710/302

(57) ABSTRACT

The present invention is a method and system for allowing hot insertion and removal of removable storage devices of a storage system removing the requirement of a power shut-down of the storage system when a removable storage device fails. An insertion/removal event may be detected and an interrupt request line corresponding to an associated adapter of the affected drive may be enabled to alert a controller of the storage system of the insertion/removal event. Receipt of the interrupt request may provide notification of the insertion/removal event and may provide isolation to the affected drive such that the rest of the associated storage system may remain operational.

### FIELD OF THE INVENTION

The present invention generally relates to the field of mass storage systems, and more particularly to a method and system for allowing hard drive hot insertion and removal.

### BACKGROUND OF THE INVENTION

Mass storage systems are becoming evermore popular as data is stored electronically. Many storage systems, such as online banking services, run continuously and users expect the ability to access their data constantly. Typical mass storage systems include a data controller that receives data requests from a host and retrieves the desired data from an array of disks. Disk arrays include multiple hard disk drives. Maintenance of storage systems includes the replacement of hard disk drives. Additionally, since hard disk drives are continually added to support increasing storage needs, storage system maintenance includes the regular insertion and removal of hard disk drives.

Problems are encountered when a disk drive fails in a storage system that provides continuous availability. In order to keep availability high, it is advantageous to employ hot swapping which refers to changing a hard disk in a system without shutting down power to the storage system. When a system supports a hot swap, a failed disk drive may be removed and replaced with a new drive. The storage system may rebuild the replaced drive after installation of the new drive. Systems that do not support hot swapping result in longer periods of data unavailability because the entire system must be shut down to replace a failed disk drive.

Storage systems known to the art which employ a Parallel Advanced Technology Attachment (PATA) storage interface do not provide for hot insertion and removal of drives. A solution to this problem involves polling of hardware by the driver/BIOS every few seconds for insertion and removal events. However, this requires excessive processor action and it is difficult to maintain the software code. Additionally, if an insertion or removal event is missed because of a delay in polling, detection of the drive insertion/removal event is only possible through manual intervention. Consequently, a method and system for allowing hot insertion and removal of removable storage devices of a storage system employing a PATA storage interface is necessary.

### SUMMARY OF THE INVENTION

Accordingly, the present invention is directed to a method and system for allowing hot insertion and removal of removable storage devices of a storage system. In an embodiment of the invention, detection of an insertion/removal event may enable an interrupt request line corresponding to an associated adapter of the affected drive. Receipt of the interrupt request referring to the insertion/removal event may provide notification of the insertion/removal event and may provide isolation to the affected drive such that the rest of the associated storage system may remain operational.

It is to be understood that both the forgoing general description and the following detailed description are exemplary and explanatory only and are not restrictive of the invention as claimed. The accompanying drawings, which are incorporated in and constitute a part of the specification, illustrate an embodiment of the invention and together with the general description, serve to explain the principles of the invention.

### BRIEF DESCRIPTION OF THE DRAWINGS

The numerous advantages of the present invention may be better understood by those skilled in the art by reference to the accompanying figures in which:

FIG. 1 depicts a block diagram of a data storage system in accordance with an embodiment of the present invention;

FIG. 2 depicts a block diagram of a system for notifying a controller of an insertion/removal event in accordance with an embodiment of the present invention; and

FIG. 3 depicts a process for notifying a controller of an insertion/removal event of a hard drive in accordance with an embodiment of the invention.

### DETAILED DESCRIPTION OF THE INVENTION

Reference will now be made in detail to the presently preferred embodiments of the invention, examples of which are illustrated in the accompanying drawings.

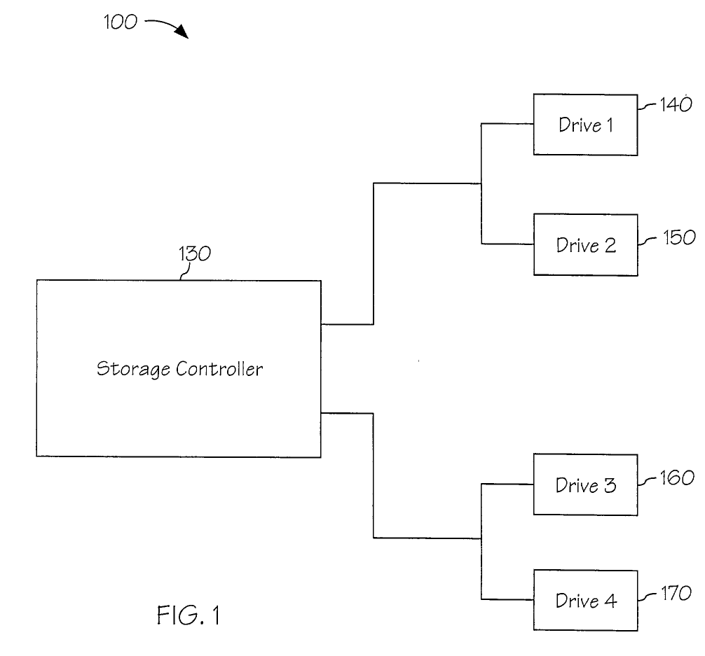

Referring to FIG. 1, a block diagram of a data storage system 100 in accordance with an embodiment of the present invention is shown. Data storage system 100 may include a storage controller 130 and a plurality of hard disk drives 140-170. Storage controller 130 may control the transfer of data to and from drives 140-170. In one embodiment of the invention, a Parallel Advanced Technology Attachment (PATA) storage interface may be employed which includes an integrated device electronics (IDE) adapter. For example, controller 130 may be a PATA controller embodied within a motherboard. Controller 130 may include two channels, wherein each channel may access two drives as shown in FIG. 1.

During the operation of a storage system 100, a removable storage device, such as a hard disk drive, may fail or additional hard drives may be added to the disk array to support additional data storage. In either scenario, maintenance of the storage system may require removal of a hard disk drive and/or insertion of a new hard disk drive. If the controller 130 cannot detect the insertion/removal event, then shut-down of the entire storage system is required in order for the controller to recognize that a new hard drive has been inserted. This is undesirable as it limits data availability to users.

In an embodiment of the present invention, a drive bay of the storage system may detect an insertion/removal event and an interrupt request line corresponding to an associated adapter of the affected drive may be enabled. Receipt of an interrupt request referring to the insertion/removal event may provide notification of the insertion/removal event. For example, if drive 2 (150) of data storage system 100 should fail, the hard drive would be removed. When the hard drive is removed, the drive bay associated with drive 2 would detect the removal and may provide a notice to raise an interrupt request line of the associated adapter of drive 2. Raising the interrupt request line may notify the controller of the removal event. When the storage controller 130 is notified of the removal event, isolation of drive 2 may occur which may provide isolation to the affected drive and eliminate the requirement of shut-down of the storage system.

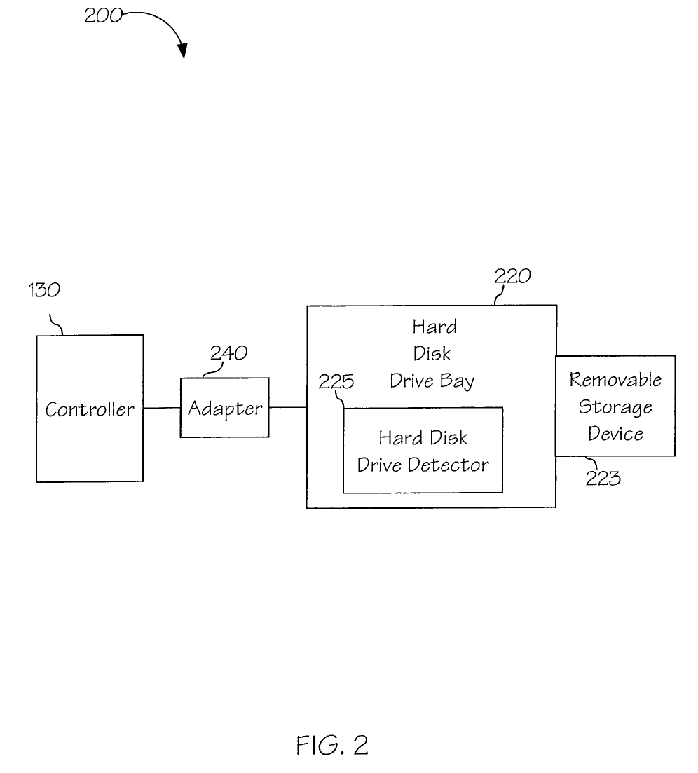

Referring now to FIG. 2, a block diagram of a system 200 for notifying a controller of an insertion/removal event in accordance with an embodiment of the present invention is shown. A hard disk drive bay 220, suitable for receiving a hard disk 223, may be equipped with a hard disk drive detector 225. The hard disk drive 220 may be coupled to an adapter 240 according to one embodiment of the invention. Adapter 240 may be coupled to a controller 130. A connection between the adapter 240 and controller 130 may include an interrupt request line. Interrupt request lines are well known to the art and may be utilized when a hard disk needs processing time. While adapter 240 is shown separately, it should be understood by those with ordinary skill in the art that the adapter may be incorporated within hard disk drive bay 220, or in an alternative embodiment, may not be utilized. In one embodiment of the invention, adapter 240 may be an IDE adapter which provides an interface between a hard drive and a controller according to an ATA specification.

In an embodiment of the invention, hard disk drive detector may be capable of detecting at least one of a change of current or voltage. For example, when a hard disk is inserted, electrical contacts of the hard disk drive bay 220 may come into physical contact with conductive contacts of a hard disk 223. When a hard disk is removed, a change in current or voltage among hard disk drive bay 220 circuitry may result. Additionally, when a hard disk 223 is inserted into a hard disk drive bay 220, a change in a current or voltage may result. As an example, a short circuit may be produced when a hard disk is inserted into a hard disk drive bay. It should be understood by those with ordinary skill in the art that a change of current or voltage may be detected which has a higher threshold than typical operating changes. It should also be understood that other types of hard disk drive detectors 225 may be employed by those with ordinary skill in the art in accordance with the present invention without departing from the scope and spirit of the present invention.

Transfer of a detection signal between hard disk drive detector 225 and adapter 240 may be implemented in various ways according to exemplary embodiments of the present invention. For example, a hardware configuration including a combination of logic gates may be utilized to transfer a detection of a removal/insertion event to the adapter such that the adapter 240 is capable of enabling an interrupt request upon the detection of a insertion/removal event. In alternative embodiments, transfer of a detection signal may be implemented with firmware and software.

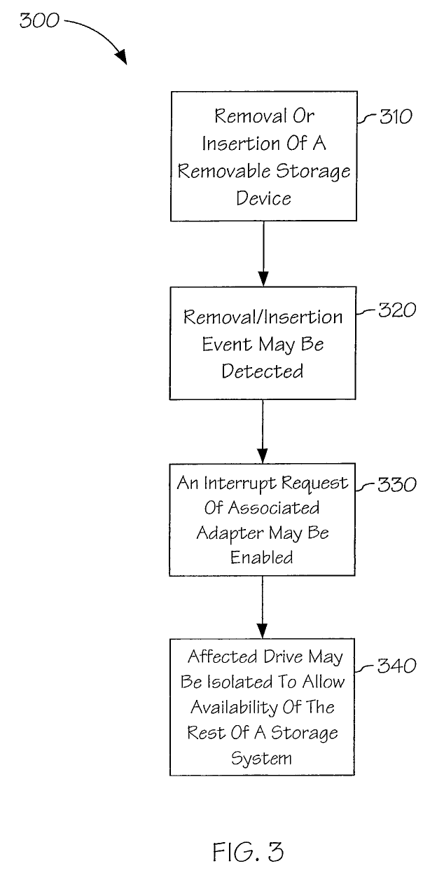

Referring to FIG. 3, a process 300 for notifying a controller of an insertion/removal event of a hard drive in accordance with an embodiment of the invention is shown. Process 300 may begin upon the removal or insertion of a hard disk drive 310. The removal/insertion event may be detected 310 through a hard disk drive detector 225 of FIG. 2. An interrupt request of an associated adapter may be enabled 330 to alert a controller of the insertion/removal event. In an advantageous aspect of the present invention, the affected drive may be isolated to allow availability of the rest of the storage system 340.

While it should be understood by those with ordinary skill in the art that a detection of an insertion/removal event would include the insertion of a hard disk into a drive bay and removal of a hard disk from a drive bay, other types of activities may also be detected. For example, operating malfunctions may be detected and a detection signal may be transferred to a storage controller of the storage system. Additionally, while in embodiments of the invention detection of an insertion/removal event of a hard disk or hard drive is employed, it should be understood by those with ordinary skill in the art that all types of removable storage devices may be utilized in accordance with the present invention without departing from the scope and spirit of the present invention.

It is believed that the system and method and system of the present invention and many of its attendant advantages will be understood by the forgoing description. It is also believed that it will be apparent that various changes may be made in the form, construction and arrangement of the components thereof without departing from the scope and spirit of the invention or without sacrificing all of its material advantages. The form herein before described being merely an explanatory embodiment thereof. It is the intention of the following claims to encompass and include such changes.

What is claimed is:

1. A method of notification of an insertion/removal event of a removable storage device of a storage system, comprising:
(a) detecting an insertion/removal event; and
(b) enabling an interrupt request line when said insertion/removal event is detected, wherein a controller is notified of an insertion/removal event.

2. The method as claimed in claim 1, wherein said detecting of said insertion/removal event senses a change in at least one of voltage and current in circuitry of a removable media drive bay.

3. The method as claimed in claim 1, further comprising the step of isolating a drive affected by said insertion/removal event.

4. The method as claimed in claim 1, wherein said storage system employs a parallel advanced technology attachment interface.

5. A system for notifying a controller of an insertion/removal event of a removable storage device of a storage system, comprising:
(a) means for detecting an insertion/removal event; and
(b) means for enabling an interrupt request line when said insertion/removal event is detected, wherein a controller is notified of said insertion/removal event via said enabling means.

6. The system as claimed in claim 5, wherein said detecting means senses a change in at least one of voltage and current in circuitry of a removable media drive bay.

7. The system as claimed in claim 5, further comprising means for isolating a drive affected by said insertion/removal event.

8. The system as claimed in claim 5, wherein said storage system employs a parallel advanced technology attachment interface.

9. A method of notification of an insertion/removal event of a removable storage device of a storage system, comprising:
(a) detecting an insertion/removal event;
(b) enabling an interrupt request line when said insertion/removal event is detected, said interrupt request line notifying a controller of said insertion/removal event; and
(c) isolating a drive affected by said insertion/removal event, wherein a removable storage device is replaceable without shutting down power to said storage system.

10. The method as claimed in claim 9, wherein said detecting of said insertion/removal event senses a change in at least one of voltage and current in circuitry of a removable media drive bay.

11. The method as claimed in claim 9, wherein said storage system employs a parallel advanced technology attachment interface.
